(19) United States
(12) Patent Application Publication
(10) Pub. No.: US 2025/0176176 A1
(43) Pub. Date: May 29, 2025

(54) FLASH MEMORY INCLUDING SELF-ALIGNED FLOATING GATES

(71) Applicant: TEXAS INSTRUMENTS INCORPORATED, Dallas, TX (US)

(72) Inventors: Robert Cassel, Lehi, UT (US); Giulio Albini, Draper, UT (US); Gowrisankar Damarla, Lehi, UT (US); Ximeng Liu, Lehi, UT (US); Gavin Wardle, South Jordan, UT (US); Ryan Rust, Lehi, UT (US); Robert Ringhofer, Draper, UT (US); Brian Ellingwood, Millcreek, UT (US)

(21) Appl. No.: 18/521,088

(22) Filed: Nov. 28, 2023

(51) Int. Cl. H10B 41/30; H01L 21/28; H01L 29/423; H01L 29/66; H01L 29/788

(52) U.S. Cl. CPC H10B 41/30; H10D 30/0411; H10D 30/683; H10D 30/6892; H10D 64/035

(57) ABSTRACT

An integrated circuit (IC) including Flash memory cells with self-aligned floating gates and a method of fabrication thereof is disclosed. A floating gate (FG) layer of polysilicon is deposited and patterned to form FG structures as part of a masking block used in forming isolation trenches. A dielectric fill material fills the isolation trenches. Subsequently, the dielectric fill material is removed using a CMP process that is configured to stop on the polysilicon of the FG structures.

### FIELD OF THE DISCLOSURE

Disclosed implementations relate generally to the field of integrated circuits (ICs) and IC fabrication. More particularly, but not exclusively, the disclosed implementations relate to an IC including Flash memory cells with self-aligned floating gates.

### BACKGROUND

A non-volatile memory (NVM), such as Flash memory, is an electronic element that is configured to retain stored information without consuming electrical energy. A threshold voltage of a Flash memory cell can be used to discriminate between logic levels of the memory cell, such as a logic low level (“0”) or a logic high level (“1”). This stored value may sometimes be referred to as information (or a bit), which may be read by sense amplifier circuitry. Although the fabrication of Flash memory cells with increased density remains a desirable goal for the semiconductor manufacturing industry, it is not without challenges as will be set forth below.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC (or IC device) including Flash memory cells with self-aligned floating gates and a method of fabricating the same. In some arrangements, prior to forming isolation trenches between Flash memory cells, a floating gate (FG) layer is formed. Subsequently, the FG layer is patterned to form FG structures of the memory cells, which comprise part of a masking block used in defining the isolation trenches. The isolation trenches are filled with one or more dielectric materials. In some arrangements, the dielectric materials used for filling the isolation trenches may be removed utilizing a selective polishing process, e.g., a chemical-mechanical polishing (CMP) process, that is configured to stop on the FG structures. In some examples, the FG structures include polysilicon.

In one example, an IC device is disclosed, which comprises, a semiconductor substrate, and at least one Flash memory cell formed in the semiconductor substrate, where the at least one Flash memory cell includes a floating gate formed over a substrate column formed in the semiconductor substrate, the floating gate having a bottom width less than or equal to a top width of the substrate column.

In one example, an IC device is disclosed, which comprises, a semiconductor substrate, and at least one Flash memory cell formed in the semiconductor substrate, where the at least one Flash memory cell includes a floating gate formed over a substrate column formed in the semiconductor substrate, the floating gate having a substantially flat bottom side parallel to a top surface of the substrate column.

In one example, a method of fabricating an IC device is disclosed. The method may comprise, among others, forming a floating gate (FG) oxide layer over a semiconductor substrate; forming an FG layer over the FG oxide layer; forming a hard mask (HM) over the FG layer; forming a secondary hard mask (SHM) over the HM; forming a patterned photoresist layer over the SHM, the patterned photoresist layer defining one or more areas for forming respective isolation trenches in the semiconductor substrate; etching through the SHM, the HM, and the FG layer to stop on the FG oxide layer, thereby forming one or more HM-FG stacks, where each HM-FG stack includes an FG structure formed from the FG layer; forming the isolation trenches between adjacent HM-FG stacks, the isolation trenches separating adjacent substrate columns formed underneath respective HM-FG stacks; forming a liner oxide along sidewalls of the respective isolation trenches; depositing a dielectric material filling the isolation trenches, the dielectric material extending over the FG structures; and polishing the dielectric material to stop on the FG structures. In some examples, the hard mask of the foregoing flow may comprise a material devoid of nitride. In some examples, the hard mask may comprise oxide. In some examples, the hard mask may comprise an organic material.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1 depicts a block diagram of an integrated circuit (IC) including an array of Flash memory cells and CMOS circuitry according to some examples of the present disclosure;

FIG. 2A depicts a cross-sectional view of a pair of Flash memory cells that may be fabricated in a process flow including a self-aligned floating gate process in accordance with some examples of the present disclosure;

FIG. 2B depicts a schematic representation of the pair of Flash memory cells depicted in FIG. 2A;

FIGS. 3A-3J depict cross-sectional views of an IC device at various stages of a process flow including a self-aligned floating gate process for fabricating Flash memory cells according to some examples of the present disclosure;

FIGS. 4A-4C are flowcharts according to some example IC fabrication methods of the present disclosure;

FIG. 5 is a representative layout of an array of Flash memory cells with self-aligned floating gates according to some examples of the present disclosure;

FIG. 6 depicts an example cross-sectional view of an IC device including the array of Flash memory cells with self-aligned floating gates depicted in FIG. 5 according to some examples of the present disclosure; and

FIGS. 7A-7C depict cross-sectional views of an IC device according to further examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of an IC including a Flash memory cell having a self-aligned floating gate (FG) and a method of manufacturing the same in a process flow will be set forth below in the context of a Flash memory cell based on a split-gate architecture.

Flash memory cells may retain stored information without consuming electrical power. Memory cells may be referred to as bitcells. In some examples, a Flash memory cell includes a floating gate (FG) configured to store information, and may be referred to as a floating-gate transistor memory cells or a floating-gate transistor bitcell. This stored information (or “bits”) can be electrically erased, programmed, and read. In some cases, an array of floating-gate transistor bitcells may be used in creating a Flash memory circuit or device. A floating-gate transistor bitcell resembles a standard metal-oxide-field-effect-transistor (MOSFET) except that the floating-gate transistor bitcell includes multiple gates (e.g., a control gate (CG) overlying a floating gate). An electrical state of a floating-gate transistor bitcell can be used to define a logic level such as a logic low level (e.g., a digital low or “0”) or a logic high level (e.g., digital high or “1”) depending on the Boolean logic used by a sense circuit for reading the data in a read operation. This defined logic level may sometimes be referred to as information (or a bit) stored in the bitcell.

Storage of information may be effectuated using changes in the floating gate (FG) characteristics of the floating-gate transistor bitcells. The threshold voltage (V_{T}) of a floating-gate transistor bitcell may change because of the presence or absence of a charge (e.g., electrons) stored in its floating gate. The stored charge alters the threshold voltage (relative to the unchanged threshold voltage) of the floating-gate transistor bitcell. For instance, in an example NMOS-based floating-gate transistor bitcell implementation, the threshold voltage is increased when electrons are stored in the floating gate of the bitcell (e.g., a “programmed” bitcell). On the other hand, the threshold voltage is decreased when electrons are depleted in (or removed from) the floating gate of the bitcell (e.g., an “erased” bitcell). Accordingly, when a voltage is applied to the control gate of a bitcell of an NMOS-based floating-gate transistor bitcell array during the read operation, the bitcell is conductive in an erased state and nonconductive in a programmed state, where each state is operative for generating a corresponding read current (I_{READ}) that is provided to a sense amplifier for sensing the data. In an example arrangement, the sense amplifier may be configured to determine the data relative to another current, referred to as a reference current (I_{REF}).

In PMOS-based floating-gate transistor bitcell implementation, these relationships are opposite, in that the PMOS-based bitcells are conductive in programmed state and non-conducting in erased state. In general, regardless of whether a PMOS-based or NMOS-based floating-gate transistor bitcell is implemented, a read current generated when the bitcell is conducting may be referred to as “ON” read current (ION), indicating a logic level of a first type. Similarly, a read current generated when the bitcell is non-conducting may be referred to as “OFF” read current (IOFF) that is indicative of a logic level of a second type complementary to the first type.

In some implementations, floating-gate transistor bitcells may utilize a split-gate architecture to store bits, and such floating-gate transistor bitcells may be referred to as split-gate FG transistor bitcells. Such a split-gate FG transistor bitcell may be regarded to include more than one transistor. For example, a split-gate FG transistor bitcell may have a gate portion (referred to as a wordline (WL) gate) adjacent to the control gate (CG) that is disposed over the floating gate (FG) used for storing information, such that the channel of the split-gate FG transistor bitcell is controlled by the wordline gate as well as the floating gate. This arrangement causes the split-gate FG transistor bitcell to act as two transistors operating in series. In some examples, two adjacent split-gate FG transistor bitcells may share a source or a drain (depending on NMOS or PMOS implementation). In general operation, a combination of one or more of the gates of a split-gate FG transistor bitcell can be configured to program, erase, and/or read the information therein.

Certain process flows using CMP process steps for fabricating the FGs of bitcells of a Flash memory array are beset with various challenges. For example, as inter-FG spacing, e.g., FG-to-FG spacing between two adjacent memory cells disposed on respective bitlines, becomes smaller, CMP design rules tend to become more restrictive, thereby rendering a technology node more susceptible to tighter process corners, which can increase the potential for defects. Accordingly, with increased pitch reduction, especially in advanced technology nodes that continue to scale to ever-shrinking geometries, the manufacturability of Flash memory arrays requiring smaller critical dimensions (CDs) (e.g., active area CDs) may be negatively impacted or otherwise limited.

In some examples, process steps based on shallow trench isolation (STI) flows may be deployed for forming active areas (e.g., substrate columns) and FG structures over the active areas. Such process steps utilize a dual CMP process. In the dual CMP process, a nitride hard mask is used to define STI trenches between active areas. The STI trenches are filled with a dielectric filler material (e.g., an oxide). Subsequently, a first CMP process (e.g., a CMP process configured to stop on the nitride hard mask) is carried out to remove the excess dielectric filler material. The nitride hard mask is removed after the first CMP process and an FG layer (e.g., polysilicon layer) is formed such that spaces between the STI trenches can be filled with the FG layer. Subsequently, a second CMP process (e.g., a CMP process configured to stop on the dielectric filler material of the STI trenches) is carried out to defines the FG structures over the active areas by removing excess polysilicon over the STI trenches.

The two separate CMP steps in the dual CMP process not only tend to increase the fabrication cost but also render the process more susceptible to variations in managing various aspects of forming the Flash memory cells with self-aligned floating gates—e.g., controlling the FG-to-active area CD ratios. Moreover, the resulting FG structure, which is a critical part of the FG transistor bitcell, ends up being a “by-product” of the two CMP steps, each aimed to stop on non-critical layers from the final FG transistor bitcell structure perspectives, namely the first CMP process stopping on the nitride hard mask (which is subsequently removed) and the second CMP process stopping on the dielectric filler material of the STI trenches. In some instances, the dual CMP process generates the FG structures with features such as “FG overhangs” or “FG wings”—e.g., a floating gate extending beyond the active area and/or potentially exhibiting curvature in the bottom side of the FG structure at both ends that “cusp” over the active area. Such features are difficult to control, and in some cases, can give rise to detrimental effects such as increased risk of cross-bitline interference, data perturbation/leakage, and the like.

Examples of the present disclosure recognize the foregoing challenges and accordingly provide a technical solution for fabricating Flash memory cells including self-aligned FG structures. In some examples, prior to forming isolation trenches between Flash memory cells, an FG layer (e.g., polysilicon) may be formed as part of a masking block that defines active areas and isolation trenches. Subsequently, a single CMP process may be implemented to define the self-aligned FG structures from the FG layer, where the single CMP process is configured to stop on the self-aligned FG structure (e.g., polysilicon of the FG structure). The CMP process may be referred to as a stop-on-poly (SOP) CMP process. In this manner, the fabrication cost as well as sources of process variations can be reduced. Moreover, as described in more detail herein, better process control may be established by appropriate selection of materials for the masking block and materials for filling the isolation trenches. As the active area formation is “pre-aligned” with the formation of FG structures (hence self-aligned FG structures), examples herein may be therefore configured to achieve enhanced control over manufacturing the Flash memory cells with self-aligned floating gate structures—e.g., FG-to-active area CD ratios. Also, some example flows may be augmented with optional FG sidewall spacers to allow further shrinkage of the FG-to-active area CD ratios as well as to provide enhanced control of corner rounding of the substrate columns formed along with overlying FG structures.

Whereas various examples of the present disclosure may be beneficially applied to manufacturing electronic devices including embedded and/or stand-alone Flash memory products based on the split-gate architecture, the teachings herein are not limited thereto and may be practiced in the manufacture of other Flash memory products (e.g., Flash memory cells based on architectures other than the split-gate architecture), which may be integrated with a broad range of CMOS logic circuits as well as other memory such as DRAM, SRAM, etc., in a single semiconductor die, depending on application and implementation, for example. While such examples and variations may be expected to reduce manufacturing defects that could otherwise reduce yields, reliability or electrical performance, no particular result is a requirement of the present disclosure unless explicitly recited in a particular claim.

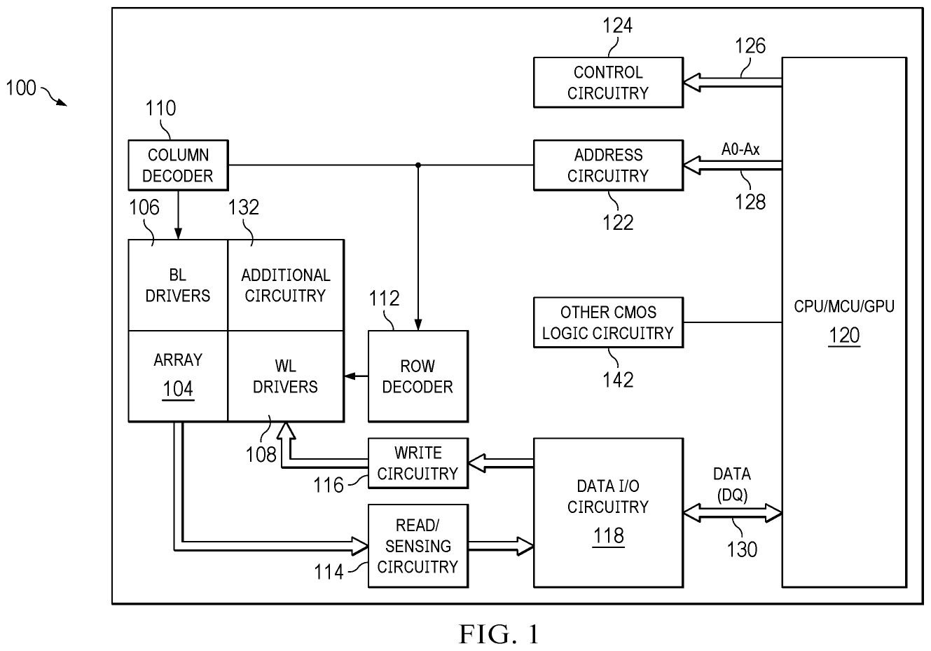

Referring now to FIG. 1, depicted therein is a block diagram of an integrated circuit (IC) including an array of Flash memory cells with self-aligned floating gates and CMOS circuitry according to some examples of the present disclosure. The array of Flash memory cells may comprise a plurality of memory cells including self-aligned floating gates fabricated utilizing a stop-on-poly (SOP) CMP process. In some examples, the SOP CMP process may be used in conjunction with a hard mask (or a masking layer) that is essentially devoid of nitride as will be set forth in detail further below. In one arrangement, IC 100 is illustrative of an electronic device fabricated on any suitable semiconductor substrate, where one or more arrays of Flash memory cells, e.g., Flash memory array 104, and associated high voltage circuitry may be formed in one or more areas or regions of the substrate, not specifically shown in this Figure.

Further, one or more remaining circuit portions of IC 100 may optionally include circuitry operable at lower voltages, which may be formed in one or more areas or regions of the substrate, also not specifically shown in this Figure. Depending on the level of integration and/or functional implementation, high voltage circuitry associated with the Flash memory array 104 may include circuitry comprising at least portions of one or more of column decoders 110, row decoders 112, bitline drivers 106, wordline drivers 108, write circuitry 116, and read/sensing circuitry 114. In some examples, at least a portion of the foregoing components, which may be generally referred to as peripheral circuits, may be formed of transistors disposed in high voltage (HV) domains operable at suitable voltages, e.g., 4.0V, 5.0V, or higher, configured to facilitate Flash memory operations, e.g., read, erase and program operations.

In some examples, the remaining circuit portions of IC 100 may include various types of electronic circuitry such as, without limitation, field-programmable gate array (FPGA) circuitry, graphics processing unit (GPU) circuitry, digital signal processor (DSP) circuitry, system-on-chip (SoC) circuitry, microprocessor (MPU) circuitry, microcontroller (MCU) circuitry, application-specific integrated circuit (ASIC) circuitry, programmable array logic (PAL) circuitry, generic array logic (GAL) circuitry, programmable logic device (PLD) circuitry, mixed-signal circuitry, analog circuitry, transducer circuitry, microelectromechanical systems (MEMS) circuitry, sense amplifier circuitry, data input/output (I/O) circuitry, neural processing unit (NPU) circuitry, artificial intelligence (AI) processing unit (AIPU) circuitry, volatile memory circuitry, macrocell array (MCA) circuitry, and programmable logic array (PLA) circuitry, and the like. Depending on implementation, the IC device 100 may include only a subset—or none—of the foregoing components or circuit portions without departing from the scope of the present disclosure.

In some arrangements, one or more foregoing components of the remaining circuit portions, where included, may be broadly defined as “CMOS logic circuitry” comprising a plurality of transistors disposed in one or more voltage domains including low voltage (LV) domains operable at, e.g., 1.0V, 1.5V, 1.8V, 3.3V, etc., without limitation. In some arrangements, Flash memory array 104 may comprise a plurality of Flash memory cells based on a split-gate architecture, which may be formed in a recessed area, whereas some of the CMOS logic portions, if included, may be formed in a non-recessed area of the substrate. Regardless of how the substrate of IC device 100 is partitioned and/or whether provided with recessed/non-recessed areas with respect to the Flash memory array 104 and/or remaining circuit portions, a description of IC 100 will be set forth below as a representative example of an electronic device including a Flash memory array, e.g., Flash memory array 104, where the self-aligned FG (the information storage components of the Flash memory cells) may be fabricated using a single SOP CMP process. Moreover, the SOP CMP process may be implemented in conjunction with a non-nitridic masking layer according to the examples described herein.

By way of illustration, a single Flash memory array and associated HV domain circuitry is shown in FIG. 1 for simplicity, although some examples of the IC device 100 may include multiple arrays, each having a respective set of Flash memory cells arranged in rows (e.g., wordlines) and columns (e.g., bitlines) as well as corresponding HV circuit portions. Depending on implementation, appropriate wordline driving circuitry 108 and bitline driving circuitry 106 may be operably coupled to the Flash memory array 104. Additional circuitry 132, which may drive lines of the Flash memory array 104 other than bitlines and wordlines may also be operatively associated with the Flash memory array 104 in some examples. In general, Flash memory cells (also referred to as Flash bitcells in some examples) arranged in the same row share a common wordline, and each wordline may be driven by a wordline driver in wordline driving circuitry 108. Likewise, Flash memory cells arranged in the same column share a common bitline, and each bitline may be driven by a bitline driver in bitline driving circuitry 106.

In some examples, the IC device 100 may include suitable processing circuitry 120, which may be configured to control the general operation of the device 100. Depending on implementation, processing circuitry 120 may provide the processing capability to execute an operating system, programs, user and application interfaces, and any other functions of the device 100. Accordingly, the processing circuitry 120 may include a general-purpose or application-specific (ASIC) processor based upon any known or heretofore unknown CPU architectures, FPGA circuitry, GPU/DSP circuitry, embedded MCU/MPU circuitry, and/or related circuitry, as previously noted.

By way of example, instructions or data to be processed by the processing circuitry 120 may be stored in the Flash memory array 104. Depending on application, the Flash memory array 104 may be configured to store a variety of information used for various purposes. For instance, the Flash memory array 104 may store firmware, such as a basic input/output system (BIOS), an operating system, various programs, applications, or any other routines that may be executed on or by the IC device 100, such as user interface functions, processor functions, and so forth. In general operation, the processing circuitry 120 may issue suitable read or write commands to retrieve data from or write data to array 104, respectively.

In some examples, the IC device 100 may include address buffer circuitry 122, which may be configured to latch address signals provided on an address bus 128 coupled to the processing circuitry 120. Address signals may be received and decoded by a row decoder 112 and a column decoder 110 to access one or more particular locations of the Flash memory array 104. For example, a wordline may be selected based upon a portion of an address value that identifies a row of the array 104, and a bitline may be selected based upon a portion of the address value that identifies a column of the array 104. The number of address input connections provided as address bus 128 depends upon the density and architecture of the Flash memory array 104. Further, appropriate sense amplifier circuitry 114 and write circuitry 116 may be provided in conjunction with data input/output (I/O) circuitry 118 for facilitating read/write operations with respect to the Flash memory array 104, where data to be stored or retrieved may be provided via a data bus 130.

In some examples, the IC device 100 may include command control circuitry 124 operable to decode command signals provided from the processing circuitry 120 by way of a control bus 126, where appropriate command signals may be provided to control the operations relative to the Flash memory array 104. For instance, the command signals may include read, program, and erase commands for reading data from, write data to, or selectively erase bitcells of the Flash memory array 104. In still further examples, various other types of CMOS logic circuitry 142 operating in different voltage domains may be provided as part of the IC device 100, which may be fabricated in remaining regions of the semiconductor substrate along with the other circuit portions of the device 100 set forth above.

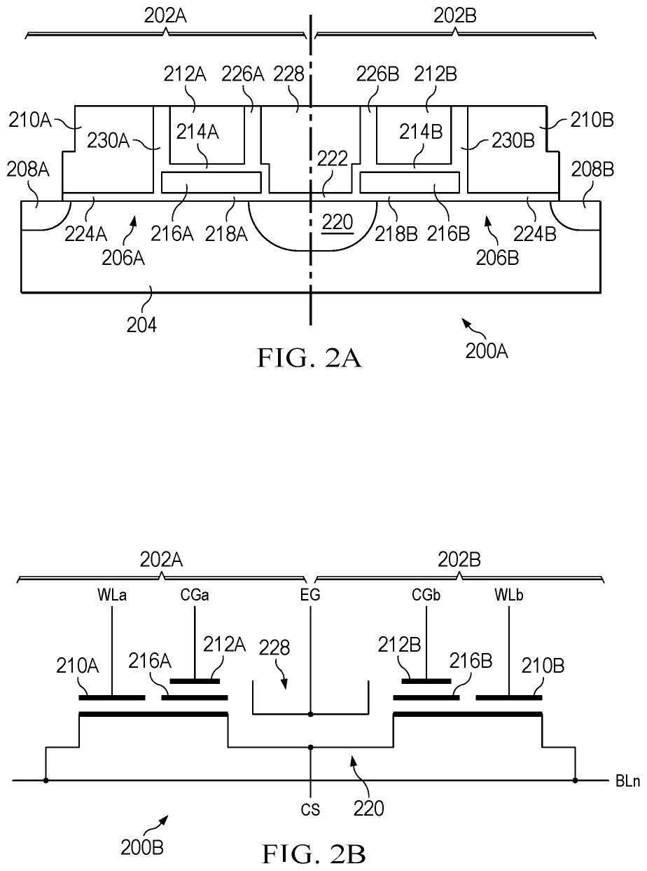

FIG. 2A depicts a cross-sectional view of a pair of adjacent Flash memory cells that may be fabricated in a process flow including a self-aligned floating gate process in accordance with some examples of the present disclosure. FIG. 2B depicts a schematic representation of the pair of Flash memory cells depicted in FIG. 2A. The pair of Flash memory cells depicted in FIGS. 2A and 2B are examples of or include aspects of Flash memory cells based on a split-gate architecture. As depicted in FIGS. 2A and 2B, the Flash memory cells include a control gate (CG), a wordline (WL), a floating gate (FG), and an erase gate (EG), where a common source (CS) terminal may be shared between two adjacent bitcells that each have a drain coupled to a bitline. Taking FIGS. 2A and 2B together, a description of the structure and general operation of example Flash memory cells is set forth below.

In an example arrangement, the split-gate FG transistor memory cell pair 200A/B comprises a first memory cell 202A and a second memory cell 202B coupled together to a same bitline BLn and may form adjacent memory cells in a column of a Flash memory array, e.g., array 104 shown in FIG. 1. Memory cells 202A and 202B may include a substrate 204 of a semiconductor die formed in a semiconductor wafer (not specifically shown). In some examples, substrate 204 may comprise a semiconductor material of a first conductivity type, such as p-type. Because memory cells 202A and 202B have an identical structure, a description of memory cell 202A is provided herein in detail, which is equally applicable to memory cell 202B. With respect to the memory cell 202A, substrate 204 includes a first region 220 and a second region 208A, both of which are of a second conductivity type, such as n-type. The first region 220 may represent a source region and the second region 208A may represent a drain region, which may be connected to the bitline BLn. The source region 220 may be shared by the memory cells 202A, 202B, which may be connected to a common source line CS. A channel region 206A may be disposed between the first region 220 and the second region 208A, which provides for conduction of charges therebetween.

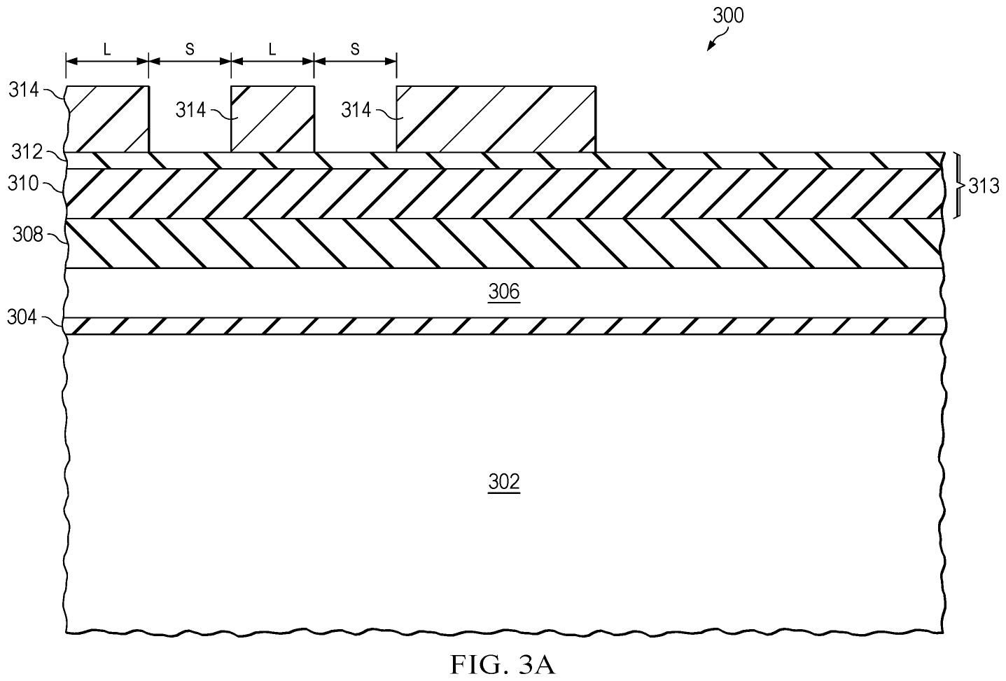

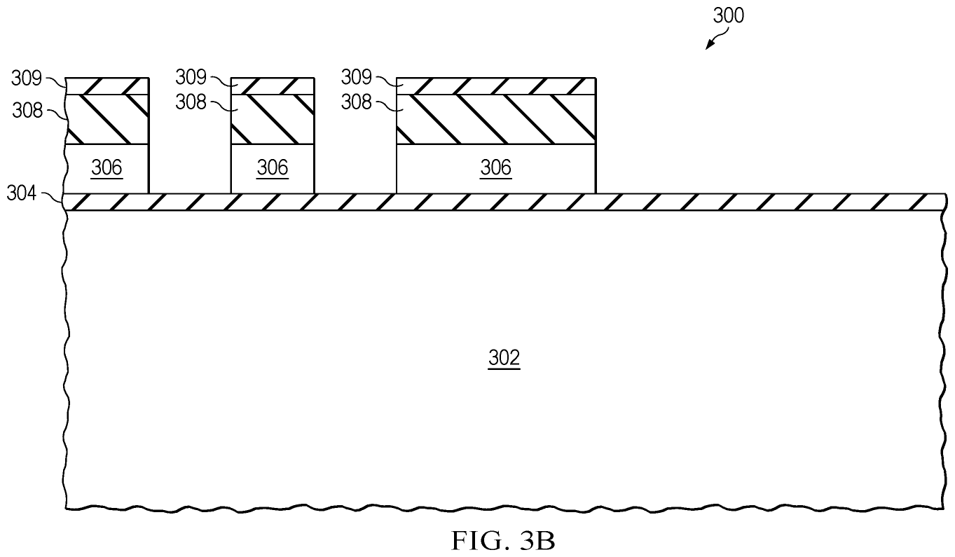

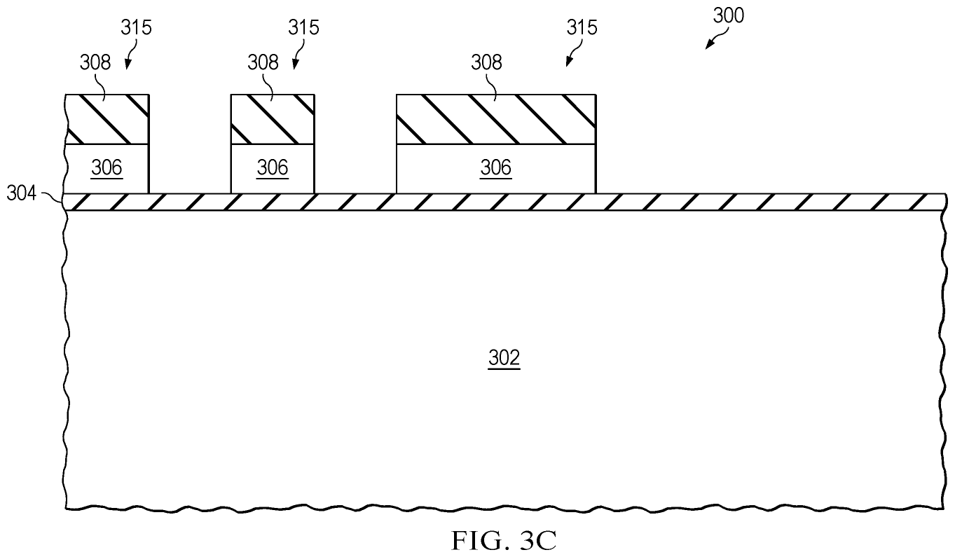

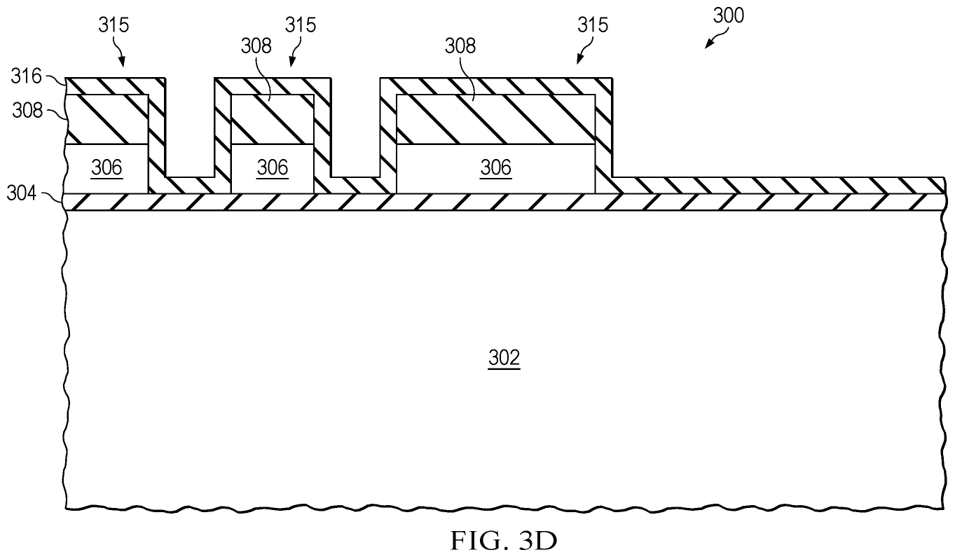

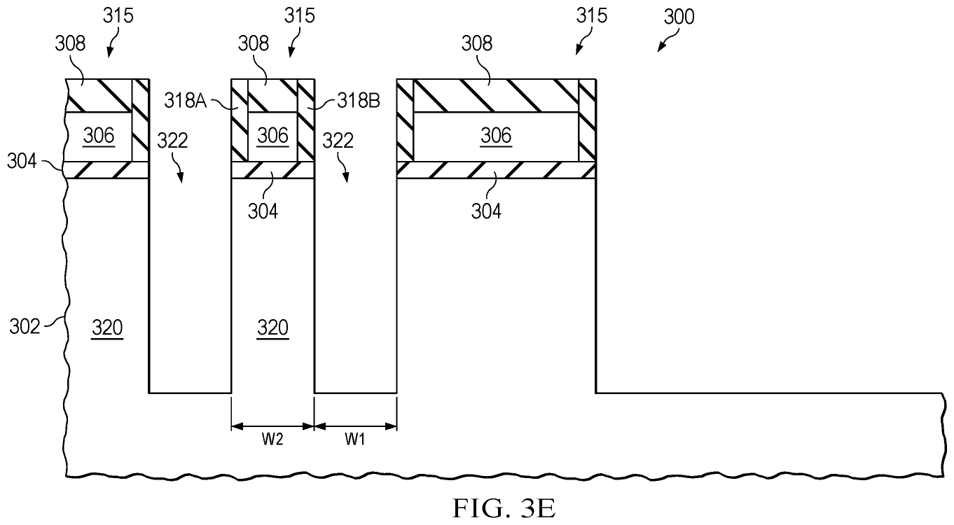

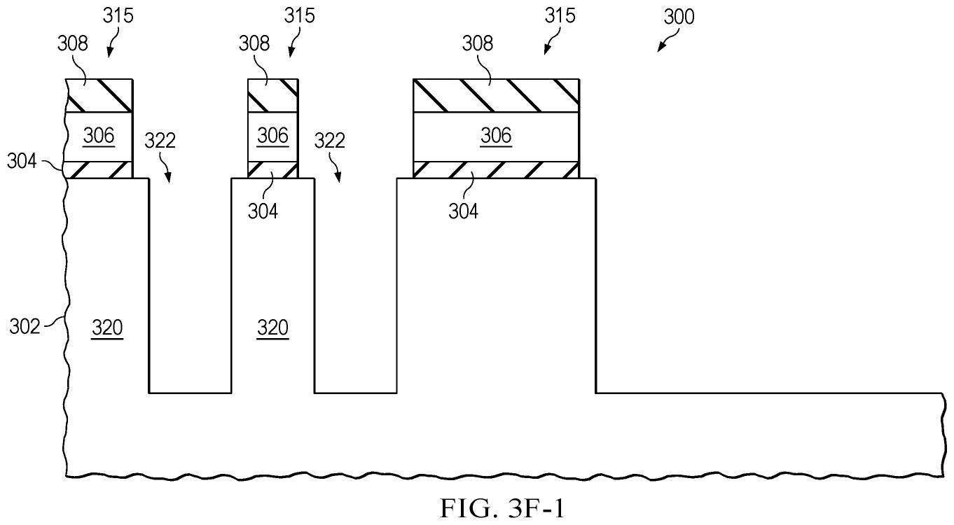

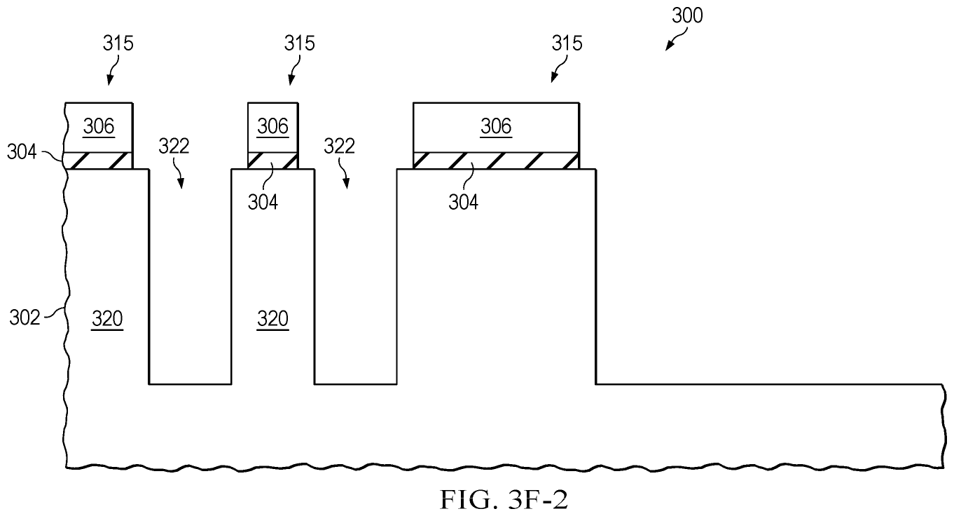

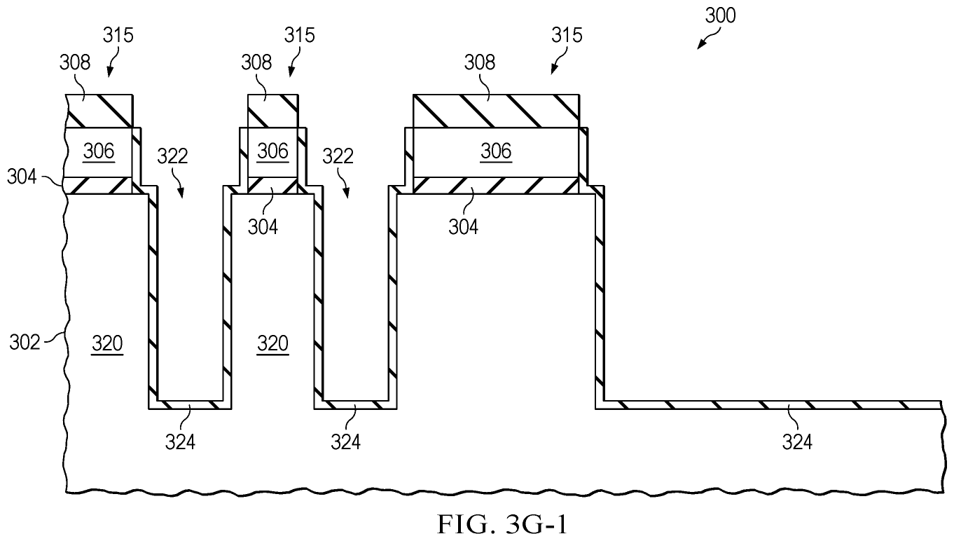

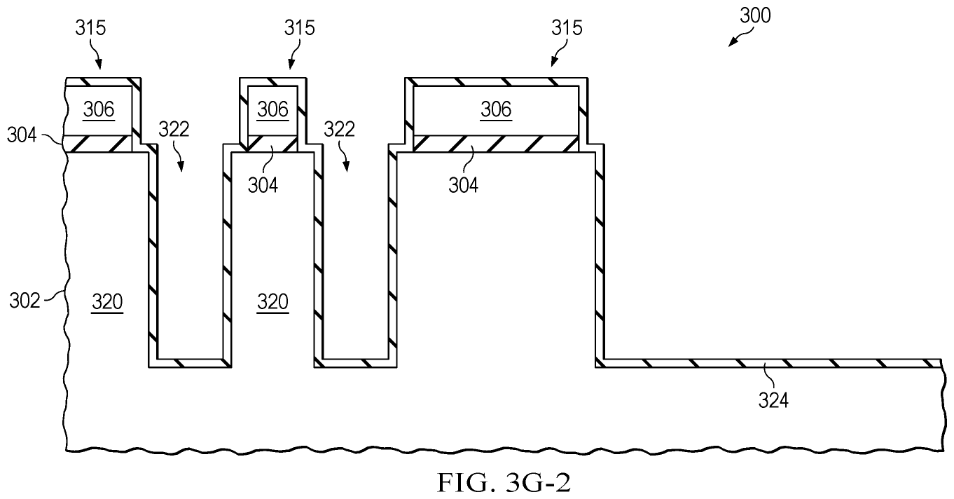

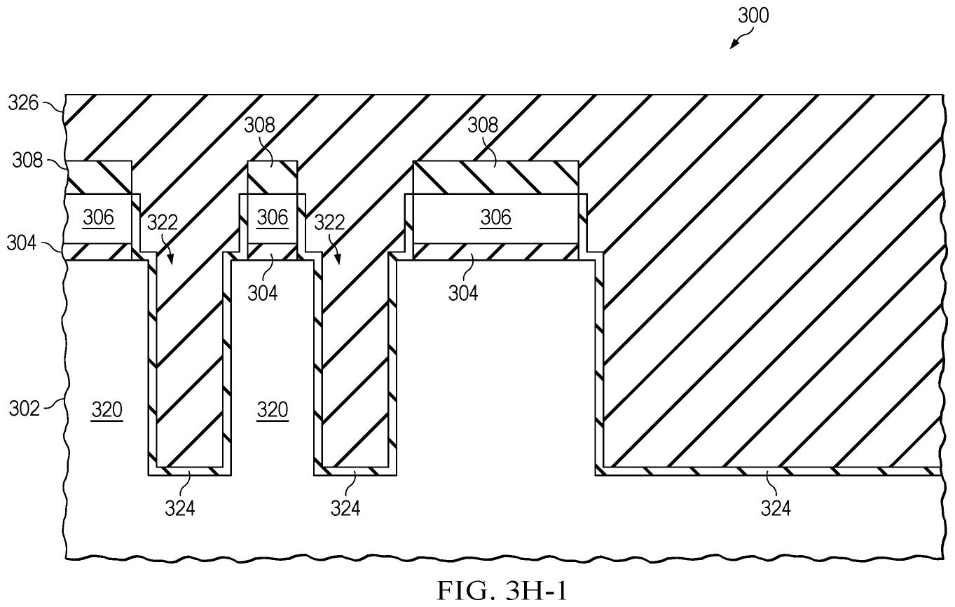

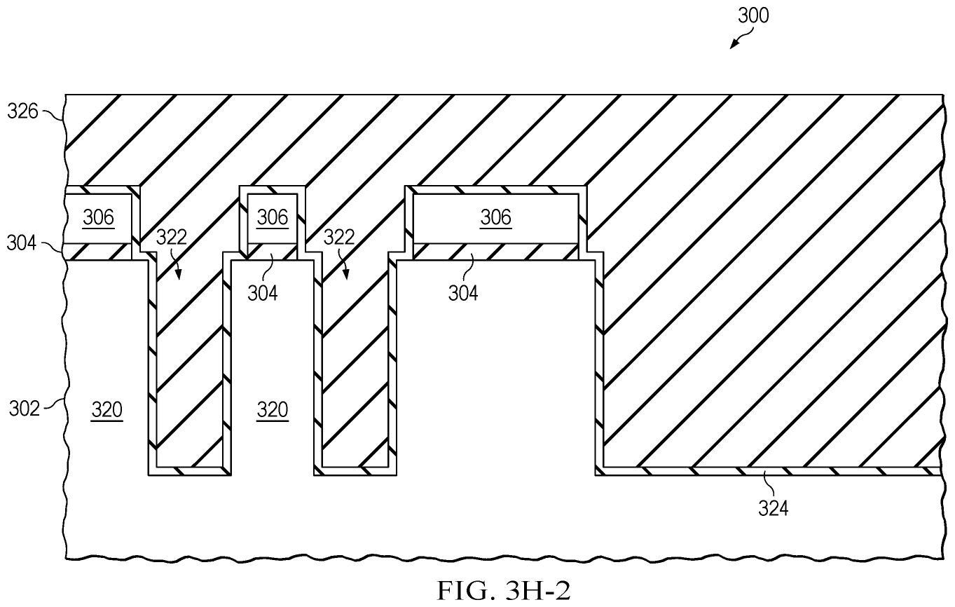

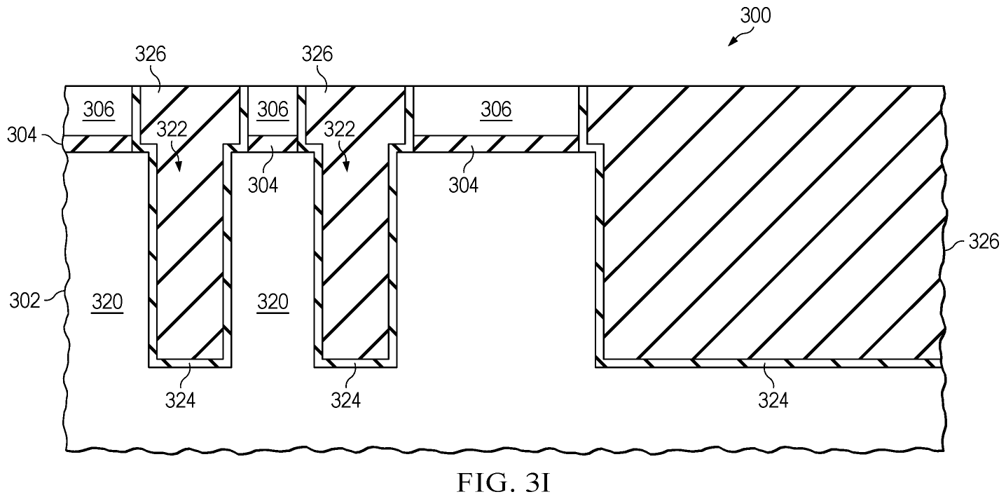

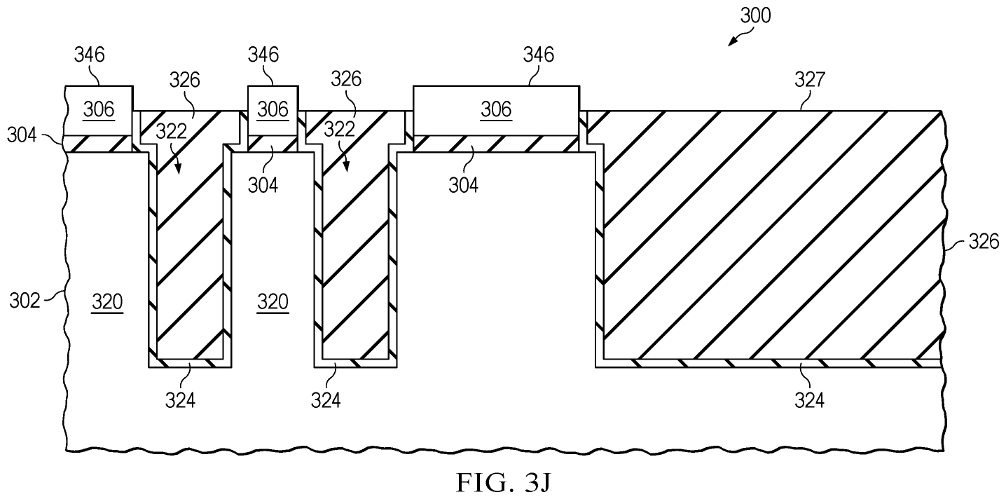

A wordline WLa forms or is otherwise connected to a select gate 210A formed over a first portion of the channel region 206A, (e.g., a portion immediately abutting the second region 208A) and insulated therefrom by a gate oxide 224A disposed between the select gate 210A and the substrate 204. Depending on implementation, the select gate 210A (also referred to as a wordline gate) may extend over a portion of the second region 208A, and may be configured to operate as a wordline transistor (also referred to as an access transistor) with respect to the memory cell 202A. A self-aligned floating gate (FG) 216A is positioned over a second portion of the channel region 206A that may be supported by a substrate column (e.g., an active area) formed in process steps generating isolation trenches between the substrate columns (not specifically shown in FIGS. 2A and 2B but described further below in reference to the cross-sectional views shown in FIGS. 3A-3J), where the floating gate 216A is laterally spaced from and disposed adjacent to the select gate 210A. The floating gate 216A is insulated from the substrate 204 by a gate oxide 218A, and may extend over a portion of the first region 220.

A control gate (CG) 212A, also referred to as a coupling gate, is disposed over the floating gate 216A and is insulated therefrom by an oxide layer 214A, thereby forming a gate stack of the memory cell 202A. For purposes of some examples of the present disclosure, a Flash memory cell or a Flash bitcell, may include a wordline gate or transistor coupled to a gate stack or a storage stack in a split-gate architecture. The control gate 212A is also positioned between the select gate 210A and an erase gate 228, and is coupled to a control gate line CGa as shown in FIG. 2B. A vertical spacer 230A, which may comprise one or more dielectric layers, insulates the select gate 210A from the control gate 212A and the floating gate 216A. The erase gate 228 is disposed over the first region 220 of the substrate 204 and is insulated therefrom by a gate oxide layer 222. The erase gate 228 is also arranged adjacent to the floating gate 216A and the control gate 212A, and is insulated therefrom by another vertical spacer 226A that may include one or more suitable dielectric layers. As depicted in FIGS. 2A and 2B, the erase gate 228 is connected to a common erase gate (EG) line shared by the memory cells 202A and 202B.

The adjacent memory cell 202B shown in FIGS. 2A and 2B has a structure identical to the memory cell 202A, as noted previously, and forms a mirror image thereof with respect to the vertical dashed line separating the two memory cells 202A, 202B and passing through the shared erase gate 228 and source region 220, as depicted in FIG. 2A. Like components in the adjacent memory cell 202B are denoted with the same reference number or initialism as corresponding components in the memory cell 202A, but with a “b” or “B” appended thereto instead of an “a” or ‘A”, as applicable. For example, component 216B is a self-aligned floating gate for the memory cell 202B, whereas like component 216A is a self-aligned floating gate for memory cell 202A, where components 216A and 212A form a gate stack of the memory cell 202A, and components 216B and 212B form a gate stack of the memory cell 202B. In some examples, the control gates 212A, 212B of memory cells 202A, 202B, respectively, may be configured to share a common control gate driver. For example, although FIG. 2B shows separate control gate lines CGa and CGb connected to control gates 212A, 212B, respectively, the control gate lines CGa and CGb may be driven by the same control gate driver (not specifically shown in the Figures).

The structure of the transistors shown in FIGS. 2A and 2B of each of the memory cells 202A and 202B provides for a separate select gate and control gate as an example of the split-gate architecture according to some examples herein. Whereas the components described in FIG. 2A for providing insulation between the various depicted structures of the memory cells 202A and 202B, such as elements 224A/B, 218A/B, 214A/B, 222, etc., are referred to as “oxides,” they may be formed using any suitable dielectric material, such as an oxide, a nitride, or a combination of an oxide and nitride, and may comprise one or more layers or sublayers of varying thicknesses. By way of illustration, the inter-gate dielectric layer 214A/B providing insulation between the control gate 212A/212B and corresponding floating gate 216A/216B may be formed from an oxide-nitride-oxide (ONO) layer in an example fabrication flow for forming the memory cells 202A/202B, where the floating gates 216A and 216B may be formed over a substrate column corresponding to a bitline, e.g., BLn, in a region of a semiconductor substrate, as will be set forth in detail further below. Further, an adjacent bitline column (e.g., BLn−1 and/or BLn+1) may be formed in similar manner supported by respective adjacent substrate columns that are laterally spaced from BLn in accordance with applicable technology-specific design rules, where control gate lines CGa, CGb as well as wordlines WLa, WLb may be disposed orthogonal to the direction of the bitlines, e.g., BLn−1, BLn, and/or BLn+1, such that the bitlines and wordlines/control gate lines define an array of memory cells.

In general operation, the memory cells 202A and 202B may be operated upon in response to commands received by suitable control circuitry of an IC device, e.g., control circuitry 124 of IC device 100, shown in FIG. 1. When either or both memory cells 202A and/or 202B are selected in response to a command, depending on whether the command indicates a read, program, or erase operation, appropriate voltages corresponding to the indicated operation may be applied to the select gate 210A/B, control gate 212A/B, erase gate 228, and source region 220 of the selected memory cell(s). A selected memory cell may refer to one identified (e.g., by an address) along with a received command, whereas an unselected memory cell is one not so identified.

By way of illustration, when memory cell 202A is selected to be erased, an erase voltage may be applied to the erase gate 228 and the other terminals of the selected memory cell 202A may be suitably biased, e.g., by applying 0V to the source 220, WL/select gate 210A, control gate 212A, and drain 208A (coupled to bitline BLn). Such biasing results in electrons tunneling from the floating gate 216A into the erase gate 228 (via Fowler-Nordheim tunneling), which causes the floating gate 216A to become positively charged, thereby lowering the cell threshold voltage. In an erased state, a read operation with respect to the selected memory cell 202A therefore results in a current flow in the channel region 206A between the drain 208A and source 220, thus indicating a logic 1. By way of example only, an erase voltage applied to the erase gate 228 during an erase operation may be a relatively high voltage, such as between approximately 8V and 14V. For instance, the erase voltage may be approximately 11V, 12V, or 13V in certain implementations.

When memory cell 202A is selected to be programmed, suitable voltages may be applied to program the memory cell 202A. For example, a relatively high voltage is applied to the control gate 212A, with lesser voltages applied to the erase gate 228, the source 220, and WL/select gate 210A (coupled to wordline WLa). A relatively small programming current may be applied to the bitline BLn, which will cause the bitline BLn to bias at a voltage. For instance, the voltage to which BLn biases may be equal to the voltage on the wordline (WLa) less the threshold voltage of the select gate 210A when the bitline BLn acts as the source. This results in a portion of the electrons in the channel region 216A that flow across the gap between the select gate 210A and the floating gate 216A acquiring enough energy to inject into the floating gate 216A via a mechanism referred to hot carrier injection. As a result, the floating gate 216A becomes negatively charged, thereby increasing the cell threshold voltage, so that a read operation results in no current flow in the channel region 206A, which may be sensed as a logic 0. By way of example only, in a program operation, a voltage of between approximately 8V and 12V may be applied to the control gate 212A, a voltage of between approximately 4V and 5V may be applied to both the source 220 and the erase gate 228, and a voltage of between approximately 0.8V and 1.3V may be applied to the select gate 210A. For instance, programming the memory cell 202A in some examples may involve applying approximately 10.5V to the control gate 212A, 4.5V to each of the source 220 and the erase gate 228, and 1V to 1.1V to the select gate 210A. A programming current applied to the bitline BLn may be between approximately 1 μA and 3 μA, which may result in the bitline BLn biasing to a voltage of approximately 0.3V.

When memory cell 202A is selected for a read operation, suitable voltages may be applied to read a data state from the memory cell 202A. In one example, 0V may be applied to the erase gate 228 and the source 220, a voltage of between approximately 2.7V and 3.3V (e.g., approximately 3.0V) may be applied to the select gate 210A, a voltage of between approximately 1.5V and 2.0V (e.g., approximately 1.8V) may be applied to the control gate 212A, and a voltage of between approximately 1.0V and 1.5V (e.g., approximately 1.2V) may be applied to the drain 208A (via bitline BLn). Depending on the amount of charge in the floating gate 216A at the time of the read operation, current will either flow (indicating a data state of 1) or not flow (indicating a data state of 0) in the channel region 206A in response to the control gate voltage. In an erased state, the absence of trapped electrons on the floating gate 216A allows for current to flow in the channel region 206A in response to applying the control gate voltage. In a programmed state, the floating gate 216A may be negatively charged due to the presence of trapped electrons, which effectively increases threshold voltage by shielding the channel region 206A from the control gate 212A, thus impeding current flow in the channel region 206A, which is indicated as a logic 0 as previously noted.

Though not shown specifically in FIG. 1, an example IC device 100 may include various driver circuits for the control gates (e.g., driving the CG lines), for the source terminals (e.g., driving the CS lines) and the erase gates (e.g., driving the EG lines) associated with a Flash memory array, e.g., Flash memory array 104, comprising a plurality of bitcells 202A/202B described in detail above. Although control gates 212A and 212B are shown as physically separate structures in FIG. 2A, they may be driven by a common control gate driver circuit fabricated using suitable HV devices in some arrangements. In further examples, a common control gate driver may be shared by more than two cells in a given column of the array, such as by four, eight, or even sixteen or more cells. In some implementations, sharing of control gate driver circuits as well as other HV domain peripheral circuits among multiple cells can serve to reduce HV circuitry area, and thus reduce overall device size and manufacturing costs.

FIGS. 3A-3J depict cross-sectional views of an IC device at various stages of a process flow including a self-aligned floating gate process for fabricating Flash memory cells according to some examples of the present disclosure. In one implementation, an example IC device 300 may include Flash memory cells such as the split-gate FG transistor memory cells 202A/202B described above, where the cross-sectional views of FIGS. 3A-3J are illustrative of views along a sectional plane perpendicular to the view depicted in FIG. 2A, e.g., a vertical plane through the gate stack 214A/216A of the memory cell 202A.

FIG. 3A depicts the IC device 300 in an early fabrication stage where a stack of one or more dielectric layers, a floating gate (FG) layer and one or more masking layers (e.g., hard mask layers) are formed over a suitable semiconductor substrate 302, followed by the formation of a photoresist layer that may be patterned for defining a plurality of isolation trenches in the substrate 302 as well as self-aligned FG structures over respective substrate columns (e.g., active areas). The semiconductor substrate 302 may predominantly comprise suitably doped silicon in some examples, although other semiconductor materials such as, Ge, SiGe, GaAs, SiC, GaN, other Group III-V materials, etc., may be used in some implementations, where one or more epitaxial layers or single-crystal layers may be formed or provided in certain areas of the substrate 302 in some arrangements.

In one implementation, an FG oxide layer 304 (e.g., a gate oxide 218A/B, also sometimes referred to as a tunnel oxide or TOX layer) having a thickness of approximately 50 Å to 200 Å, without limitation, may be formed over the semiconductor substrate 302. In some arrangements, the FG oxide layer 304 may be grown in an in-situ stream generation (ISSG) oxidation process although other methods for forming an oxide layer may be used in additional and/or alternative examples. Various process parameters such as temperature, pressure, hydrogen flow and oxidation time may be modulated in an example ISSG process to obtain a suitable thickness of FG oxide layer 304 depending on the technology and application.

In an example arrangement, an FG layer 306 comprising suitable conductive material may be formed over the FG oxide layer 304. The FG layer 306 may have an initial thickness that may be dependent on the desired final thickness of the FG structures resulting from subsequent processing stages, e.g., CMP, etch-backs, etc., as will be set forth further below. In one implementation, the FG layer 306 may comprise polysilicon (e.g., deposited in a furnace) having an initial thickness of about 500 Å to 1000 Å, without limitation. In some additional and/or alternative arrangements, the FG layer 306 may comprise in-situ doped polysilicon, amorphous polysilicon, etc. The final target thickness of the FG structures resulting from patterning the FG layer 306 and subsequent processing may be achieved depending on the ratio of a height of the isolation structure (e.g., a portion of the isolation structure extended above the FG oxide layer 304) to the initial thickness of the FG layer 306, among other factors. In some examples, the final target thickness of the FG structure may vary between 150 Å and 600 Å. In a CMOS portion of the IC device, however, the FG layer 306 may be completely removed.

A hard mask (HM) 308 (or a first masking layer) of suitable thickness, e.g., about 600 Å to 1000 Å, may be formed over the FG layer 306, where the HM 308 comprises a non-nitridic material (e.g., devoid of nitride), which may be silicon oxide (e.g., SiOₓ) or organic hard mask material, depending on implementation. In an example arrangement, SiOₓ may be deposited as a hard mask (or a masking layer) using a plasma enhanced CVD (PECVD) process. In some additional and/or alternative arrangements, the organic hard mask material may include amorphous carbon, organo-siloxane based materials with reflection control properties, etc., which may be deposited either by CVD process or spin-on processes.

In some examples, a secondary hard mask (SHM) 313 (or a second masking layer) comprising one or more layers of suitable materials may be formed over the first, or primary, HM 308, for facilitating better control over the photolithography process used for forming HM-FG stacks including respective self-aligned FG structures. According to one implementation, SHM 313 may comprise a spin-coated multi-layer resist (MLR) mask of about 2000 Å to 3000 Å, including an underlayer (UL) 310 that is thicker than an overlayer (OL) 312. In some examples, UL 310 may have a thickness of about 1800 Å to 2500 Å, comprising organic materials, ashable hard mask (AHM) materials, diamond-like carbon (DLC) films, etc. In some examples, OL 312 may have a thickness of about 200 Å to 500 Å, comprising a silicon-containing hard mask bottom anti-reflection coating (SHB) and/or a dielectric anti-reflection coating (DARC) layer. In some arrangements, an SHM may comprise multiple additional hard mask layers as needed for accommodating appropriate mask margins. Depending on implementation, any of the foregoing HM layers may be formed using various types of CVD processes, spin-on processes, and the like.

A photoresist (PR) layer 314 having a thickness of about 900 Å to 1500 Å may be formed over SHM 313, which may be patterned for facilitating the formation of a plurality of HM-FG stacks (e.g., HM-FG stacks 315) that serve as a masking block in subsequent process steps for forming isolation trenches separated by respective substrate columns. The patterned PR layer 314 may have openings identified as “S” for defining a plurality of isolation trench areas in the substrate 302, whereas blocking areas identified as “L” in the patterned PR layer 314 may correspond to the regions in the substrate 302 that form respective substrate columns (e.g., active areas) separated by the adjacent isolation trenches. In an example arrangement, an immersion lithography process may be implemented to enhance the resolution of the patterning.

FIG. 3B depicts a cross-sectional view of the IC device 300 after the completion of a first etch process in an example implementation, where a suitable etch process may be configured to stop on the FG oxide layer 304 while removing the materials of SHM 313, HM 308 and FG layer 306 not blocked by the PR pattern. In some arrangements, there may be a residual portion 309 of the SHM materials, e.g., material from UL 310, that may remain after the etch stage, as illustrated in FIG. 3B. Such residual portion 309 may be removed in a subsequent in-situ carbon strip (ISCS) process, resulting in HM-FG stacks 315 as illustrated in FIG. 3C. In some additional and/or alternative arrangements, e.g., where the first etch stage may be configured to completely remove the SHM 313 (MLR-UL material), an ISCS process may not be required. In general, where a carbon-based SHM material may remain after the first etch stage, an ISCS process may be implemented in order to remove the residual SHM material so as to facilitate a cleaner deposition of a sidewall spacer oxide layer (e.g., FG sidewall spacer oxide layer 316 via atomic layer deposition) over the patterned HM-FG stacks 315.

FIG. 3D depicts a cross-sectional view of the IC device 300 after depositing an optional FG sidewall spacer oxide layer 316 over the patterned HM-FG stacks 315, which may extend over the FG oxide layer 304 not underlying the patterned HM-FG stacks 315. In one arrangement, the FG sidewall spacer oxide layer 316 may be about 30 Å to 100 Å thick, deposited using a plasma enhanced ALD (PEALD) process. Depending on implementation, the thickness of the FG sidewall spacer oxide layer 316 may vary based on the desired shrinkage of the FG-to-active area CD ratio, which may allow for the avoidance of the FG structure overhangs as well as for providing sufficient FG structure pullback with respect to corresponding edges of the isolation trenches. In some examples, exposing corners of the active areas (substrate columns) by pulling back the FG structure facilitates rounding the corners of the active areas to avoid undesirable consequences stemming from having relatively sharp corners.

A second etch process having suitable anisotropic etch characteristics, e.g., a dry etch or reactive ion etch (RIE), may be performed to form isolation trenches 322 separated by respective substrate columns 320 in the semiconductor substrate 302, as illustrated in FIG. 3E. Also depicted in FIG. 3E are sidewall spacers 318A/318B formed along respective sidewalls of the HM-FG stacks 315. Depending on implementation, the isolation trenches 322 may have a depth of about 100 nanometers (nm) to 1000 nm—e.g., with respect to the interface between the FG oxide 304 and the substrate 302. Analogously, respective substrate columns 320 may have corresponding heights—e.g., with respect to the base (or bottom) of the isolation trenches 322. Further, the widths (W1) of isolation trenches 322 and the widths (W2) of substrate columns 320 may be suitably dimensioned based on applicable CD and pitch rules, where the isolation trenches 322 and corresponding substrate columns 330 may have tapered profiles (e.g., the trenches 322 narrowing towards the bottom while the columns widening towards the top, not specifically shown in FIG. 3E).

In an example implementation where sidewall spacers 318A/318B have been formed as a result of the second etch process as set forth above, the sidewall spacers 318A/318B may be removed in a subsequent etch process. Regardless of the formation of sidewall spacers and subsequent removal thereof, surface of the substrate columns 320 may be oxidized to form an oxide layer (e.g., forming a liner oxide layer 324 on the surface of the substrate columns 320 described with reference to FIG. 3G). As a result of the oxidation process, corners (e.g., top corners) of the substrate columns 320 may be rounded. Subsequently, the isolation trenches 322 are filled with a suitable fill material (e.g., a dielectric material 326 described with reference to FIG. 3H). In other words, the fill material forms on the oxide liner on the surface of the substrate columns 320. Thereafter, excess fill material may be polished using a suitable CMP process that stops on the FG structures patterned from the FG layer 306. Hereinafter, the FG structures are designated with the reference numeral 306 as the FG structures are formed from the FG layer 306.

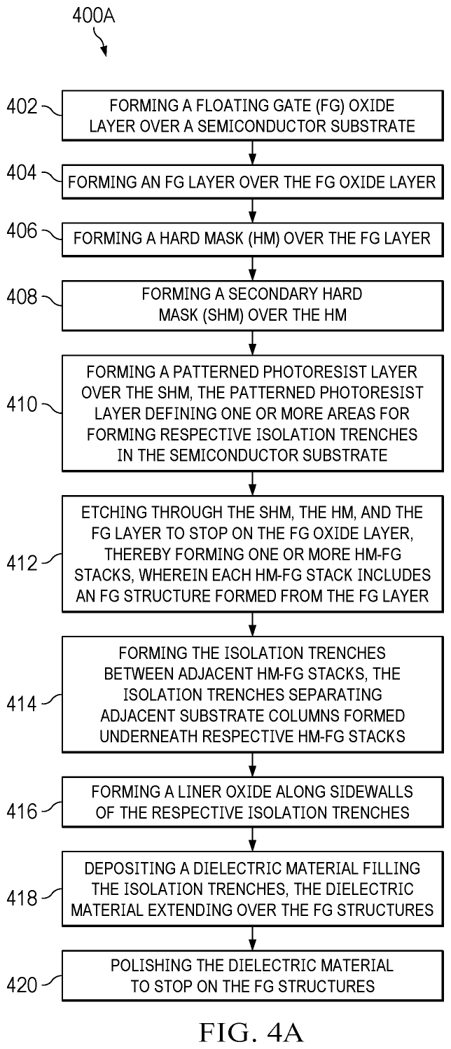

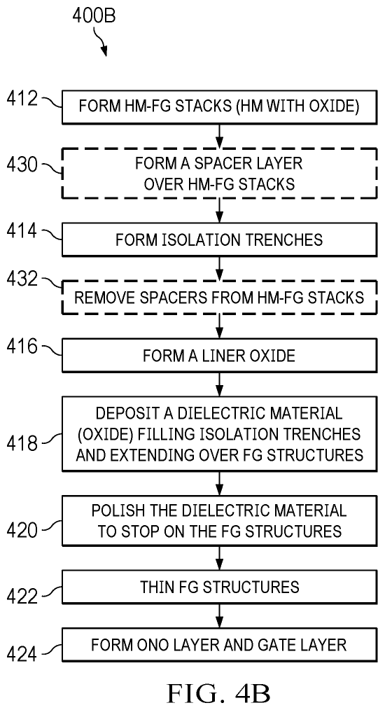

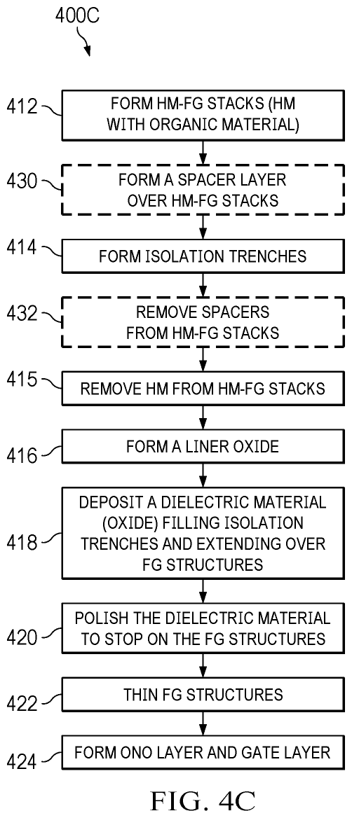

Depending on the type of hard mask material used for forming HM 308, e.g., oxide HM (OXHM) material (SiOₓ) or organic HM (ORHM) material, example process sequences with respect to the above-described stages may be varied accordingly, which will be set forth below in reference to the cross-sectional views of FIGS. 3F-1 to 3H-2 as well as in view of the flowcharts of FIGS. 4A-4C of the present disclosure.

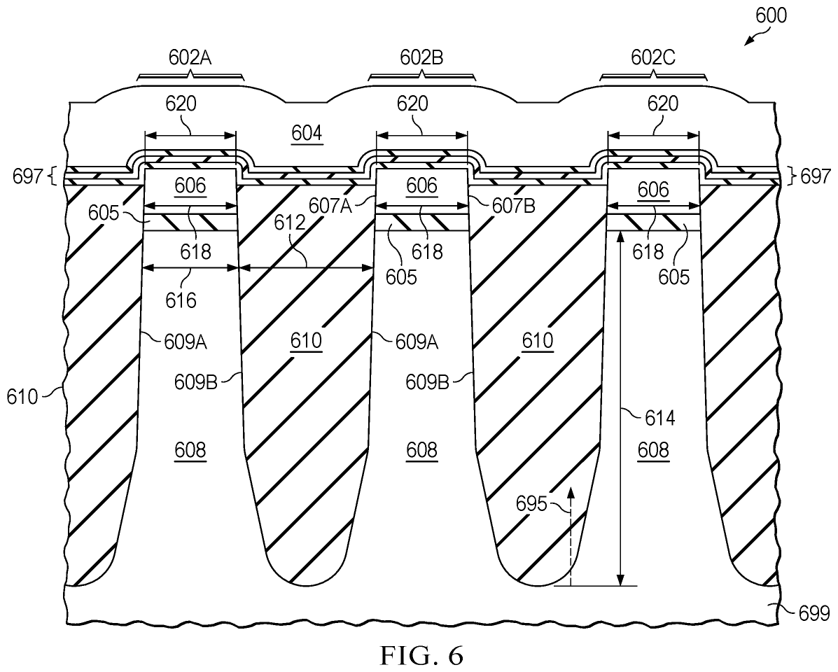

In a first example where OXHM material (e.g., SiOₓ) is used as HM 308, the hard mask material may remain as part of the HM-FG stacks 315, as shown in FIG. 3F-1, which illustrates the IC device 300 at a stage with the sidewall spacers 318A/318B removed. Subsequently, a liner oxide layer 324 of suitable thickness may be formed, e.g., via ISSG, covering at least a portion of the sidewalls of the FG structures 306, vertical walls of the respective substrate columns 320, as well as the exposed horizontal surfaces of the substrate columns 320, as illustrated in FIG. 3G-1. Thereafter, a suitable dielectric material 326 may be deposited over the IC device 300 to fill the isolation trenches 322 and extending over the HM-FG stacks 315, e.g., as shown in FIG. 3H-1. A similar process flow may also be implemented where there are no sidewall spacers provided, resulting in FG structures 306 without any pullback (or offset), e.g., having sidewalls of the FG structures 306 that are vertically aligned with respective sidewalls of the corresponding substrate columns 320—e.g., as depicted in FIG. 6.

In a second example where ORHM material is used as HM 308, the hard mask material may be removed prior to forming a liner oxide layer 324 and depositing the dielectric fill material (e.g., a dielectric material 326 described with reference to FIG. 3H) over the IC device 300. Where sidewall spacers 318A/318B have been formed along with the isolation trenches 322 and corresponding substrate columns 320, the sidewall spacers 318A/318B may be removed by an oxide removal process as before, which may be followed by an ORHM strip process for stripping the ORHM material from the HG-FG stacks resulting in “truncated” stack structures, also referred to herein with reference numbers 315, that do not include HM components, as illustrated in FIG. 3F-2. In an example, the ORHM strip process may be implemented for removing the ORHM material without affecting the underlying polysilicon FG structures 306 of the stacks 315 and/or the exposed silicon surface of the substrate columns 320. Subsequently, a liner oxide layer 324 of suitable thickness may be formed, e.g., via ISSG, covering the sidewalls as well as the top surfaces of the FG structures 306, vertical walls of the substrate columns 320, and the exposed planar horizontal surfaces of the substrate columns 320, similar to the oxide liner process set forth above. Thereafter, a suitable dielectric material 326 may be deposited over the IC device 300 to fill the isolation trenches 322 and extending over the patterned FG structures 306, e.g., as shown in FIG. 3H-2. A similar process flow may also be implemented in the ORHM scenario where there are no sidewall spacers provided, resulting in FG structures 306 having sidewalls that are vertically aligned with respective sidewalls of the corresponding substrate columns 320—e.g., as depicted in FIG. 6.

In one arrangement, the dielectric materials 326 deposited over the IC device 300 in the foregoing example flows may comprise suitable oxide material, which may be deposited using a variety of techniques. In one example, a high density plasma (HDP) CVD process may be implemented using a gas mixture comprising silane, oxygen, and argon, where the argon gas pressure, chamber pressure, and the sputter RF energy may be maintained at appropriate levels. In some arrangements, the HDP process may be configured as a cyclic PECVD process involving a deposition-etch-deposition-etch approach. Certain HDP process may not require an additional annealing step. In another example, a high aspect ratio process (HARP) may be implemented that also involves PECVD, which may require an additional densification step to fully oxidize the dielectric film. Some HARP implementations may therefore involve nitrogen annealing at around 1000° C. to 1200° C. and/or a stream anneal process at around 700° C. to 800° C. In another example, a PEALD process may be implemented for depositing the dielectric fill material 326, which may also involve nitrogen annealing at around 1000° C. to 1200° C. In yet another example, the dielectric fill material 326 may be deposited using a spin-on-dielectric (SOD) process that may require steam densification.

Turning to FIG. 3I, shown therein is a cross-sectional view of the IC device 300 after completing a CMP process having a high degree of selectivity (e.g., a selectivity greater than 100:1 (oxide:polysilicon), a selectivity greater than 200:1 (oxide:polysilicon), without limitation) that is configured to stop on the FG structures 306. Such a CMP process may be referred to as a stop-on-polysilicon (SOP) CMP process. The SOP CMP process is expected to prevent (e.g., substantially reduce) corners of the FG structure 306 from being eroded during the polishing process. In some examples, maintaining overall shapes of the FG structures 306 during the CMP process may facilitate reducing oxide dishing (e.g., the oxide adjacent to the FG structures 306). In this manner, the final polysilicon thicknesses of the FG structure 306 utilizing the SOP CMP process are tighter distribution—e.g., when compared with the final polysilicon thicknesses of the FG structure 306 utilizing the dual CMP process described above.

Still referring to FIG. 3I, the SOP CMP process generates the IC device 300 of FIG. 3I regardless of using the oxide HM (OXHM) material (SiOₓ) or the organic HM (ORHM) material. In other words, in the first example using the OXHM material, the SOP CMP process can be performed on the IC device 300 of FIG. 3H-1 polishing the oxide material 326 and the oxide HM (OXHM) until the SOP CMP process stops on the FG structures 306 as depicted in FIG. 3I. Similarly, in the second example using the ORHM material, the SOP CMP process can be performed on the IC device 300 of FIG. 3H-2 polishing the oxide material 326 and the liner oxide layer 324 until the SOP CMP process stops on the FG structures 306 as depicted in FIG. 3I. In this manner, the SOP CMP process can be devised to have such a high selectivity between oxide and polysilicon removal rates in view of no other materials (e.g., nitride) to remove. Moreover, the single SOP CMP process generates the FG structures 306 such that overall process cost can be reduced and certain sources of process variations can be eliminated (e.g., when compared to the dual CMP process described above).

Thereafter, one or more etch back steps may be performed to achieve different thicknesses of the FG structures 306 and/or to expose sidewalls of the FG structures 306—e.g., to increase a gate-coupling ratio between the FG structures and the control gate structures). Moreover, the FG structures formed in CMOS logic regions of the IC device 300 may be removed, e.g., by using appropriate masking steps and etch steps. In some arrangements, a top surface 327 of the dielectric material 326 may be lower than a top surface 346 of the FG structures 306 as a result of the one or more etch back steps. In some examples, the one or more etch back steps may remove at least a portion of the liner oxide layer 324 (e.g., ISSG oxide) from the sidewalls of FG structures 306 as shown in FIG. 3J.

FIGS. 4A-4C are flowcharts according to some example IC fabrication methods, which may be combined in various ways according to one or more arrangements of the present disclosure. Flowchart 400A shown in FIG. 4A is illustrative of a method for forming an IC device having an array of Flash memory cells with self-aligned floating gates, which may commence with forming a floating gate (FG) oxide layer over a semiconductor substrate (block 402), followed by forming an FG layer over the FG oxide layer as set forth at block 404. Thereafter, a first or primary HM comprising non-nitridic material (e.g., oxide HM or organic HM) may be formed over the FG layer as set forth at block 406. At block 408, a secondary HM (SHM) may be formed over the primary HM, where the SHM may comprise multiple layers as previously described. At block 410, a patterned photoresist layer may be formed over the SHM, where the patterned photoresist layer is operable to define one or more areas for forming respective isolation trenches in the semiconductor substrate. At block 412, the SHM, the HM, and the FG layer may be etched through in a first etch process, which may be configured to stop on the FG oxide layer, thereby forming one or more HM-FG stacks, where each HM-FG stack includes an FG structure formed from the FG layer. Subsequently, a second etch process may be performed for forming the isolation trenches between adjacent HM-FG stacks, where the isolation trenches separate adjacent substrate columns formed underneath respective HM-FG stacks (block 414). At block 416, a liner oxide layer may be formed along sidewalls of the respective substrate columns, where an ISSG process for growing the oxide layer may be implemented as previously described. At block 418, a dielectric material may be deposited for filling the isolation trenches, where the dielectric material extends over the FG structures. At block 420, the dielectric material may be polished (e.g., a CMP process having high selectivity) to stop on the FG structures—e.g., after removing excess dielectric material and achieving suitable planarization.

Flowchart 400B shown in FIG. 4B is illustrative of IC fabrication methods that may include an oxide HM as the primary HM and optional sidewall spacers in fabricating an IC device, where additional, alternative, and/or optional steps may be augmented with the flowchart 400A set forth above. Accordingly, at block 412, a plurality of HM-FG stacks are formed where an oxide HM is provided as the primary HM. An optional spacer layer may be formed over the HM-FG stacks as set forth at block 430. After forming the isolation trenches (block 414), the resulting spacers may be removed from the HM-FG stacks as set forth at block 432. Thereafter, blocks 416-420 set forth above may follow. Subsequently, the FG structures may be thinned, e.g., by one or more etch back operations, to expose sidewalls of the FG structures as set forth at block 422. At block 424, an inter-gate oxide-nitride-oxide (ONO) layer of suitable thickness (which may include aspects of the inter-gate dielectric layer 214A) and a polysilicon control gate (CG) layer (which may include aspects of the control gate 212A) may be formed over the thinned FG structures in order to form the completed Flash memory cells such as bitcells 202A/202B depicted in FIGS. 2A and 2B. In some examples, the ONO layer may have a thickness of about 100 Å to 150 Å, without limitation. In some examples, the polysilicon CG layer may have a thickness of about 300 Å to 600 Å, without limitation.

Flowchart 400C shown in FIG. 4C is illustrative of IC fabrication methods that may include an organic HM as the primary HM and optional sidewall spacers in fabricating an IC device, where additional, alternative, and/or optional steps may be augmented with the flowchart 400A set forth above, similar to the flowchart 400B. Accordingly, at block 412, a plurality of HM-FG stacks are formed where organic material (e.g., devoid of nitride) is provided as the primary HM. An optional spacer layer may be formed over the HM-FG stacks as set forth at block 430. After forming the isolation trenches (block 414), the resulting spacers may be removed from the HM-FG stacks as set forth at block 432. Prior to forming a liner oxide, the organic HM is removed from the HM-FG stacks as set forth at block 415. Thereafter, blocks 416-424 set forth above may follow for completing the fabrication of the Flash memory cells having self-aligned FG as part of the gate stacks.

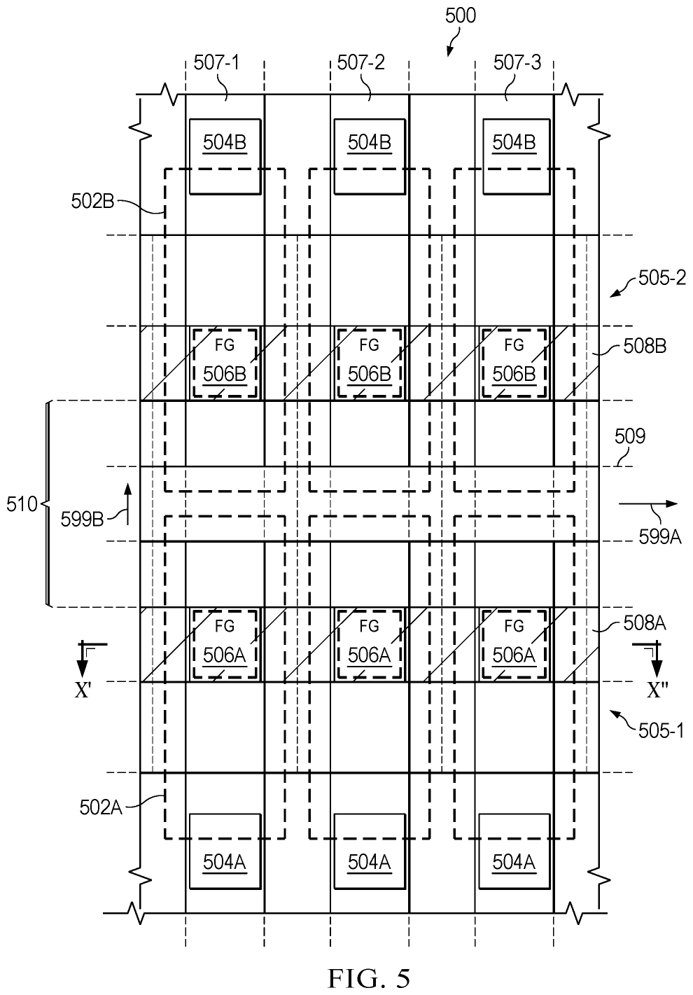

FIG. 5 depicts a representative layout of an array of Flash memory cells having self-aligned floating gates according to some examples of the present disclosure. As illustrated, the layout 500 includes a plurality of rows 505-1, 505-2 (e.g., wordline gates or select gates 210A/210B of FIG. 2A) extending along a first direction, e.g., X-direction 599A, and a plurality of active areas 507-1 to 507-3 (e.g., substrate columns 320 that form bitlines of the array) extending along a direction, e.g., Y-direction 599B, orthogonal to the first direction. By way of example, reference numbers 502A, 502B refer to a pair of split-gate bitcells roughly corresponding to the split-gate bitcells 202A, 202B of FIGS. 2A/2B, where bitcells 502A, 502B include the active area 507-1. Each bitcell 502A/502B includes a floating gate (FG) 506A/506B that is self-aligned to the underlying active area 507-1. Control gates 508A, 508B (e.g., control gates 212A/212B of FIG. 2A) extending along the X-direction 599A are associated with the bitcells 502A, 502B, respectively. In similar fashion, a common erase gate 510 (e.g., erase gate 228 of FIG. 2A) located between the control gates 508A, 508B extends along the X-direction 599A in the example layout 500. Also depicted in the layout 500 is the source 509 (e.g., the source 220 of FIG. 2A) extending along the X-direction 599A. Drain contacts 504A, 504B associated with bitcells 502A, 502B (e.g., drain contacts 504A/504B coupled to the drain regions 208A/208B of FIG. 2A), respectively, are also illustrated in the example layout 500. In the representation depicted in FIG. 5, FGs 506A, 506B are shown without a lateral pullback (or offset) of the FG 506A/506B with respect to the edges of the active area 507-1, e.g., along the X-direction 599A. In other words, the sidewalls of FGs 506A, 506B are aligned with respective first and second sidewalls of the substrate column corresponding to the active area 507-1.

FIG. 6 depicts an example cross-sectional view of an IC device including the array of Flash memory cells with self-aligned floating gates depicted in FIG. 5 according to some examples of the present disclosure. By way of illustration, an example IC device 600 is shown with three bitlines 602A-602C, each formed over a respective substrate column 608 (e.g., substrate column 320) that are separated by respective isolation trenches 610 formed in a substrate 699, roughly corresponding to a cross-sectional view taken along a vertical sectional plane X′-X″ shown in the example layout 500 of FIG. 5. As previously noted, isolation trenches 610 may have a suitable depth 614 and a top width 612 depending on the IC device type and functionality, where the isolation trenches 610 may have tapering sidewalls toward the bottom, e.g., a tapering of around 75° to 90° relative to a respective surface normal 695 in reference to a horizontal plane of the substrate 699. In a non-limiting example, the tapering angles of an isolation trench's sidewalls may be around 85° to 87° relative to the surface normal 695. Each substrate column 608 is isolated from a respective floating gate 606 (e.g., floating gate structure 306) by a corresponding FG oxide 605 (e.g., FG oxide 304). An inter-gate dielectric layer 697 comprising, e.g., ONO layer, is disposed over the floating gates 606, which underlies a control gate 604 (e.g., control gate 212A/212B) running across the plurality of bitlines 602A-602C.

In some arrangements, a floating gate 606 may have a bottom width 618 that may be less than or equal to a top width 616 of a corresponding substrate column 608. Where the bottom width 618 of the floating gate 606 is less than the top width 616 of the substrate column 608, it may be less than by about 2 nm or greater. In some arrangements, a floating gate 606 may have a first sidewall 607A and a second sidewall 607B that are vertically aligned with respective first and second sidewalls 609A, 609B of the corresponding substrate column 608. In some arrangements, the first and second sidewalls 607A, 607B of the floating gate 606 may be substantially parallel to the respective first and second sidewalls 609A, 609B of the corresponding substrate column 608. In some arrangements, a floating gate 606 may have a substantially flat bottom side that is parallel to a top surface of the corresponding substrate column 608, i.e., without exhibiting a curvature on the bottom side facing the substrate column 608. In some arrangements, the first and second sidewalls 607A, 607B of the floating gate 606 may be substantially straight and orthogonal to the top surface of the substrate column 608. In some arrangements, a top width 620 of the floating gate 606 may be less than or equal to a width, e.g., bottom width 618, of the bottom side of the floating gate 606.

Whereas dual CMP processes for fabricating Flash memory generally involve the patterning of a floating gate polysilicon layer after the formation of isolation trenches using a nitride mask, which results in poor FG-to-active area CD control as previously described, example methods herein provide for forming a FG layer that is subsequently patterned for forming FG structures in HM-FG stacks, which are then used as part of a masking block structure for forming the isolation trenches, thereby advantageously aligning the FG structures to the active area regions with better CD control. Further, a spacer oxide (e.g., a spacer formed by ALD process) may be provided for facilitating FG pullback that exposes active area corner and, concomitantly, improved the corner rounding with respect to the substrate columns, e.g., substrate columns 608 described above. Because non-nitridic HM material is used as a primary HM in forming the self-aligned FG structures, subsequent SOP CMP processing configured to stop on polysilicon of the FG structure is better controlled at least partially due to the similarity of CMP characteristics of the trench fill material and the HM material in some examples. Further, as the risk associated with FG overhangs is reduced, with or without sidewall spacers, IC devices having denser bitline pitches may be fabricated with fewer manufacturability and/or storage performance issues.

Although some example implementations may involve NMOS-based split-gate FG transistor bitcells, the teachings herein are not limited thereto. Some example implementations may include PMOS-based FG transistor bitcells. Moreover, the teachings herein can be applied to a Flash memory cell other than the split-gate architecture in additional and/or alternative arrangements. Whereas various S/D implants, extension region implants (e.g., LDD implants) as well as additional implants such as halo/pocket implants, and the like may be used in some examples, not all such types of implants are required. Accordingly, a variety of bitline/drain implant profiles may be implemented where LDDs and/or halo/pocket implants are not necessary or may be optionally provided. Further, example implementations may involve various Flash architectures, e.g., single-level cell (SLC) Flash architectures (storing one bit of data per cell), multi-level cell (MLC) Flash architectures (storing more than one bit per cell), NAND-based Flash architectures, NOR-based Flash architectures, charge trap Flash architectures, etc.

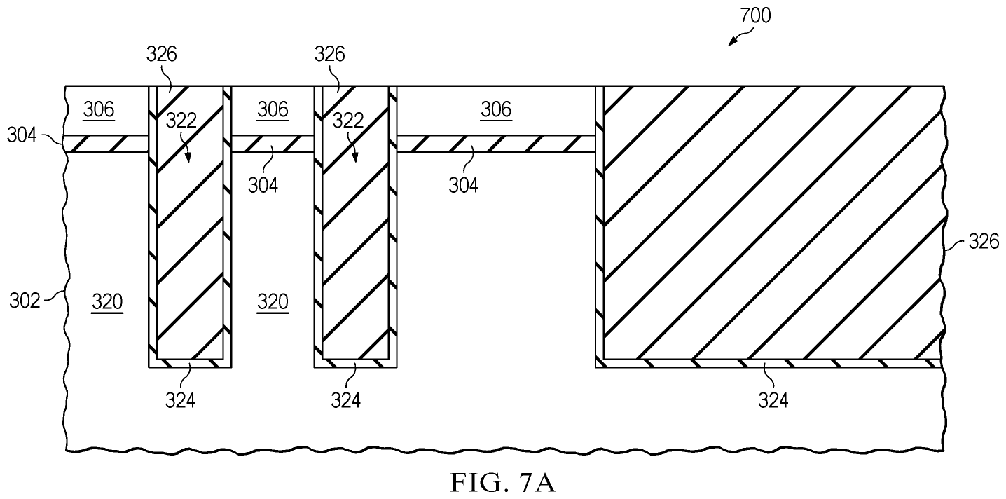

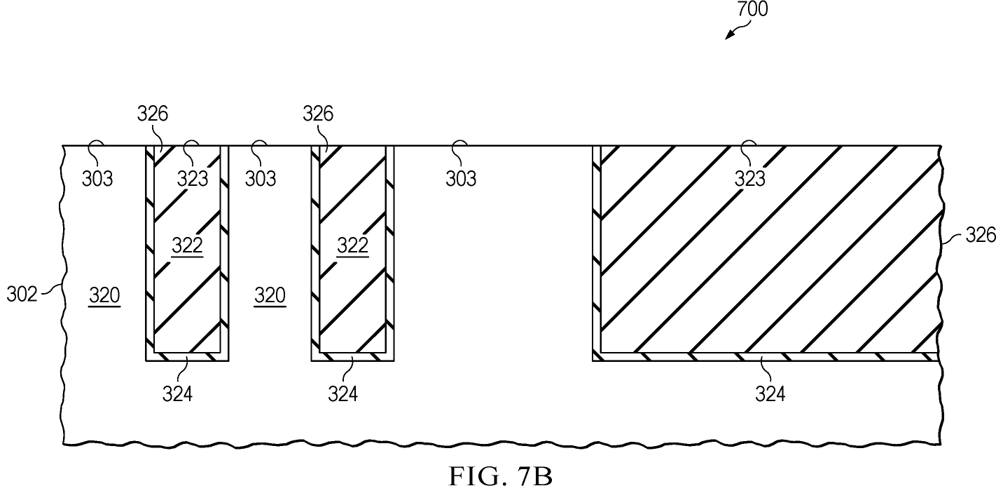

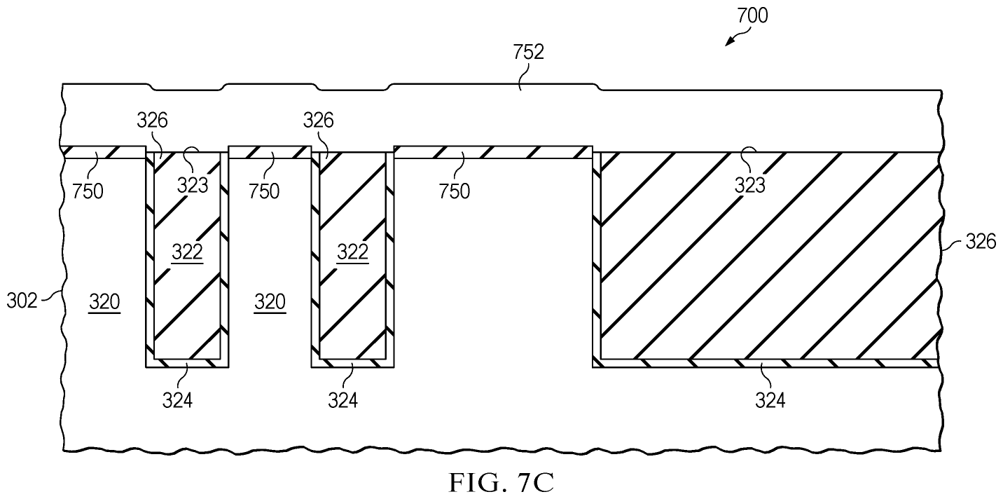

Also, above-described example process flows include forming transistors without floating gates, for example, metal-oxide-semiconductor (MOS) transistors of various functional blocks (e.g., column decoders 110, row decoders 112, bitline drivers 106, wordline drivers 108, write circuitry 116, read/sensing circuitry 114) of the IC 100 described with reference to FIG. 1. Furthermore, above-described example process flow is not limited to fabricating ICs including Flash memory cells. In other words, the above-described example process flows can be practiced in a process flow for building MOS transistors only (e.g., non-Flash process flow). In a non-Flash process flow, the FG layer and resulting FG structures described above may be regarded as an additional hard mask layer or a sacrificial layer enabling the SOP CMP process described above. FIGS. 7A through 7C describes various process steps of forming transistors without the floating gates—e.g., the non-Flash functional blocks of the IC 100, an IC without Flash memory cells.

FIG. 7A is a cross-sectional view of an IC device 700 (e.g., an IC device including aspects of the IC device 300, an IC without Flash memory cells) after completing the SOP CMP process described with reference to FIG. 3I. The cross-sectional view of FIG. 7A may be a portion of the various functional blocks (e.g., column decoders 110, row decoders 112, bitline drivers 106, wordline drivers 108, write circuitry 116, read/sensing circuitry 114) of the IC 100 or a portion of an IC without Flash memory cells. Also, the cross-sectional view of FIG. 7A illustrates that sidewalls of the FG structures 306 may be vertically aligned with respective sidewalls of the substrate columns 320. For example, the process steps associated with forming the sidewall spacers 318A/318B may be omitted or the process steps associated with forming the sidewall spacers 318A/318B may be modified such that the FG sidewall spacer oxide layer 316 may be selectively removed outside the Flash memory array 104.

Subsequently, the FG structures 306 may be removed as shown in FIG. 7B. Moreover, FIG. 7B illustrates that the dielectric material 326 of the isolation trenches 322 (along with a portion of the liner oxide layer 324 extended above the substrate columns 320 in some cases) and the FG oxide 304 are removed. As shown in FIG. 7B, the substrate 302 including the isolation trenches 322 becomes substantially planar. For example, the surface 323 of the dielectric material 326 of the isolation trenches 322 may be substantially coplanar with the surface 303 of the substrate columns 320. In other examples, the surface 323 of the dielectric material 326 of the isolation trenches 322 may extend above the surface 303 of the substrate columns 320—e.g., by an amount of at least a portion of a gate oxide 750 to be formed on the substrate columns 320 as described with reference to FIG. 7C.

FIG. 7C is a cross-sectional view of the IC device 700 after forming a gate oxide and a gate layer on the substrate 302 that has been substantially planarized as described with reference to FIG. 7B. For example, FIG. 7C illustrates the gate oxide 750 formed (e.g., by ISSG process) on the surface 303 of the substrate columns 320. In some examples, a thickness of the gate oxide 750 may vary between 1 nm and 10 nm. Subsequently, the gate layer 752 (e.g., polysilicon) is deposited on the gate oxide 750. The surface of the gate layer 752 is also substantially planar (e.g., flat) such that subsequent patterning of the gate layer 752 to form gate structures of the MOS transistors can avoid processing complexity that may originate from a non-planar surface of the gate layer 752.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise. Where some examples may describe certain quantities, values, variables, parameters, entities or other features in terms of relative degree such as “about”, “approximately, “substantially” and the like, such terms may refer to a certain variable percentage or range of the stated value of the referenced quantity, variable, parameter, etc. that may vary depending on the context, e.g., ±10% of a stated value in some cases, ±15% of a stated value in some cases, ±20% of a stated value in some cases, and so on.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An integrated circuit (IC), comprising:
a semiconductor substrate; and
at least one Flash memory cell formed in the semiconductor substrate, the at least one Flash memory cell including a floating gate formed over a substrate column formed in the semiconductor substrate, the floating gate having a bottom width less than or equal to a top width of the substrate column.

2. The IC as recited in claim 1, wherein the bottom width of the floating gate is less than the top width of the substrate column by about 2 nanometers or greater.

3. The IC as recited in claim 1, wherein the floating gate has a first sidewall and a second sidewall, the first and second sidewalls of the floating gate vertically aligned with respective first and second sidewalls of the substrate column.

4. The IC as recited in claim 1, wherein the floating gate has a first sidewall and a second sidewall, the first and second sidewalls of the floating gate are substantially parallel to respective first and second sidewalls of the substrate column.

5. The IC as recited in claim 1, wherein the substrate column is laterally spaced apart from an adjacent substrate column by an isolation trench formed in the semiconductor substrate, the isolation trench filled with a dielectric material.

6. The IC as recited in claim 5, wherein the dielectric material is devoid of nitride.

7. The IC as recited in claim 1, further comprising a floating gate (FG) oxide layer disposed between the floating gate and the substrate column.

8. An integrated circuit (IC), comprising:
a semiconductor substrate; and
at least one Flash memory cell formed in the semiconductor substrate, the at least one Flash memory cell including a floating gate formed over a substrate column formed in the semiconductor substrate, the floating gate having a substantially flat bottom side parallel to a top surface of the substrate column.

9. The IC as recited in claim 8, wherein the floating gate has a first sidewall and a second sidewall, the first and second sidewalls of the floating gate substantially straight and orthogonal to the top surface of the substrate column.

10. The IC as recited in claim 8, wherein a top width of the floating gate is less than or equal to a width of the bottom side of the floating gate.

11. The IC as recited in claim 8, wherein the bottom side of the floating gate has a width less than or equal to a top width of the substrate column.

12. A method of fabricating an integrated circuit (IC), the method comprising:
forming a floating gate (FG) oxide layer over a semiconductor substrate;
forming an FG layer over the FG oxide layer;
forming a hard mask (HM) over the FG layer;
forming a secondary hard mask (SHM) over the HM;
forming a patterned photoresist layer over the SHM, the patterned photoresist layer defining one or more areas for forming respective isolation trenches in the semiconductor substrate;
etching through the SHM, the HM, and the FG layer to stop on the FG oxide layer, thereby forming one or more HM-FG stacks, wherein each HM-FG stack includes an FG structure formed from the FG layer;
forming the isolation trenches between adjacent HM-FG stacks, the isolation trenches separating adjacent substrate columns formed underneath respective HM-FG stacks;
forming a liner oxide along sidewalls of the respective isolation trenches;
depositing a dielectric material filling the isolation trenches, the dielectric material extending over the FG structures; and
polishing the dielectric material to stop on the FG structures.

13. The method as recited in claim 12, wherein the hard mask comprises a material devoid of nitride.

14. The method as recited in claim 12, wherein the hard mask comprises oxide.

15. The method as recited in claim 14, further comprising:
prior to forming the isolation trenches and the liner oxide, forming a sidewall spacer layer over the one or more HM-FG stacks, wherein forming the isolation trenches includes forming sidewall spacers from the sidewall spacer layer along respective sidewalls of the one or more HM-FG stacks; and
after forming the isolation trenches, removing the sidewall spacers from the respective HM-FG stacks, wherein forming the liner oxide includes covering top corners of the substrate columns exposed as a result of removing the sidewall spacers.

16. The method as recited in claim 15, wherein the liner oxide vertically extends to cover at least a portion of the respective sidewalls of the one or more HM-FG stacks.

17. The method as recited in claim 12, wherein the hard mask comprises an organic material.

18. The method as recited in claim 17, further comprising:
prior to forming the liner oxide and depositing the dielectric material in the isolation trenches, removing the hard mask from the one or more HM-FG stacks, wherein forming the liner oxide along the sidewalls of the respective isolation trenches includes extending the liner oxide over the FG structures.

19. The method as recited in claim 17, further comprising:
prior to forming the isolation trenches and the liner oxide, forming a sidewall spacer layer over the one or more HM-FG stacks, wherein forming the isolation trenches includes forming sidewall spacers from the sidewall spacer layer along respective sidewalls of the one or more HM-FG stacks; and
after forming the isolation trenches, removing the sidewall spacers and the hard mask from the respective HM-FG stacks, wherein forming the liner oxide includes covering top corners of the substrate columns exposed as a result of removing the sidewall spacers.

20. The method as recited in claim 12, further comprising thinning the FG structures for forming respective floating gates of corresponding Flash memory cells of the IC.

21. The method as recited in claim 20, wherein the thinning includes etching back the dielectric material of the isolation trenches to recess below a top surface of the respective floating gates.

22. The method as recited in claim 20, further comprising:
forming an oxide-nitride-oxide (ONO) layer over the floating gates; and
forming a control gate layer over the ONO layer.

23. The method as recited in claim 12, wherein the FG layer comprises polysilicon.

24. The method as recited in claim 12, further comprising:
removing the FG structures in an area of the semiconductor substrate, the area configured to include a circuit having metal-oxide-semiconductor (MOS) transistors of the IC.

25. The method as recited in claim 24, further comprising:
etching back the dielectric material of the isolation trenches; and
removing the FG oxide layer exposed as a result of removing the FG structures.

26. The method as recited in claim 25, wherein, as a result of etching back the dielectric material of the isolation trenches, a first surface of the dielectric material of the isolation trenches is substantially coplanar with a second surface of the substrate columns.

27. The method as recited in claim 25, further comprising:
forming a gate oxide of the MOS transistors; and
forming a gate layer of the MOS transistors on the gate oxide.
